(19) United States
(12) Patent Application Publication
(10) Pub. No.: US 2006/0011949 A1
(43) Pub. Date: Jan. 19, 2006

(54) METAL-GATE CMOS DEVICE AND FABRICATION METHOD OF MAKING SAME

(76) Inventors: Chih-Wei Yang, Kao-Hsiung Hsien (TW); Yi-Sheng Hsieh, Tai-Chung Hsien (TW); Wei-Min Lin, Hsin-Chu Hsien (TW); Wei-Tsun Shiau, Kao-Hsiung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/160,449

(22) Filed: Jun. 24, 2005

Related U.S. Application Data
(60) Provisional application No. 60/521,892, filed on Jul. 18, 2004.

(51) Int. Cl. H01L 27/10; H01L 21/8238

(52) U.S. Cl. 257/204; 438/199

(57) ABSTRACT

A metal-gate complementary metal-oxide-semiconductor (CMOS) device is disclosed. The CMOS device includes a PMOS transistor formed on a first area of a substrate and a NMOS transistor formed on a second area of the substrate and being coupled to the PMOS transistor. The PMOS transistor includes a first gate stack consisting of a first dielectric layer, a first single-layer metal directly stacked on the first dielectric layer, and a first conductive capping layer directly stacked on the first single-layer metal. The NMOS transistor includes a second gate stack consisting of a second dielectric layer, a second single-layer metal directly stacked on the second dielectric layer, and a second conductive capping layer directly stacked on the second single-layer metal.

### CROSS-REFERENCES TO RELATED APPLICATIONS

This application claims priority from U.S. provisional application No. 60/521,892 by Yang et al., filed Jul. 18, 2004, entitled “Method for integrating dual metal gate electrodes with high dielectric constant material”.

### BACKGROUND OF INVENTION

1. Field of the Invention

The present invention relates generally to the field of semiconductor fabrication. More particularly, this invention relates to a metal-gate complementary metal-oxide-semiconductor (CMOS) device and fabrication method of making same.

2. Description of the Prior Art

The continued scaling of CMOS devices into sub-70 nm technology will rely on a fundamental change in transistor gate stack materials. Over the past few years, research in this area has focused on identifying candidate materials to replace poly-silicon and SiO₂ as the gate electrode and gate dielectric, respectively. Critical requirements for novel gate electrode materials include thermal stability with the gate dielectric and suitable values for the interfacial work function (˜4.0 eV and ˜5.0 eV for bulk-Si NMOS and PMOS devices respectively). The latter requirement of obtaining complementary gate work functions on a single wafer is being perceived as a major process integration challenge.

Metal-gate electrodes bring about several advantages compared to traditional polysilicon gates as CMOS technology continues to scale beyond the 100 nm node. These include reduction in poly-depletion effect, reduction in sheet resistance, and potentially better thermal stability on high-K gate dielectrics. The main challenge is that, unlike with polysilicon, one would have to use two metallic materials (bi-layer metal) with different work functions in order to achieve the right threshold voltages for both NMOS and PMOS. A straightforward way to implement dual metal CMOS is to etch away the first metal from either NMOS or PMOS side, and then deposit a second metal with a different work function.

Unfortunately, this would entail exposing the gate dielectric to the metal etchant, leading to undesirable dielectric thinning and likely reliability problems. Further, the prior art methods of making metal-gate CMOS devices are complex and have process integration issues.

### SUMMARY OF INVENTION

It is a primary object of the claimed invention to provide a semiconductor manufacturing method that is able to eliminate the above-mentioned problems.

The invention achieves the above-identified and other objects by providing a method of fabricating a metal-gate complementary metal-oxide-semiconductor (CMOS) device. A semiconductor substrate having a first region and a second region is provided. A first dielectric layer is then deposited over the semiconductor substrate. A first metal layer is formed over the first dielectric layer. A capping layer is deposited over the first metal layer. The first region is masked while exposing the second region. The capping layer, the first metal layer and the first dielectric layer are etched away from the second region. A second dielectric layer is then deposited over the semiconductor substrate. The second dielectric layer covers the capping layer. A second metal layer is formed over the second dielectric layer. The second region is masked while exposing the first region. The second metal layer, the second dielectric layer and the capping layer are etched away from the first region. A conductive layer is deposited on the first metal layer and on the second metal layer. Lithographic and etching processes are performed to form a first gate stack comprising the first dielectric layer, the first metal layer and the conductive layer within the first region, and a second gate stack comprising the second dielectric layer, the second metal layer and the conductive layer within the second region.

From one aspect of this invention, a metal-gate complementary metal-oxide-semiconductor (CMOS) device is disclosed. The CMOS device comprises a PMOS transistor formed on a first area of a substrate and a NMOS transistor formed on a second area of the substrate and being coupled to the PMOS transistor. The PMOS transistor comprises a first gate stack consisting of a first dielectric layer, a first single-layer metal directly stacked on the first dielectric layer, and a first conductive capping layer directly stacked on the first single-layer metal. The NMOS transistor comprises a second gate stack consisting of a second dielectric layer, a second single-layer metal directly stacked on the second dielectric layer, and a second conductive capping layer directly stacked on the second single-layer metal.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a cross-sectional view of a metal-gate CMOS device according to the preferred embodiment of this invention; and

FIG. 2 to FIG. 7 are schematic diagrams showing a method of forming a metal-gate CMOS device according to the preferred embodiment of this invention.

### DETAILED DESCRIPTION

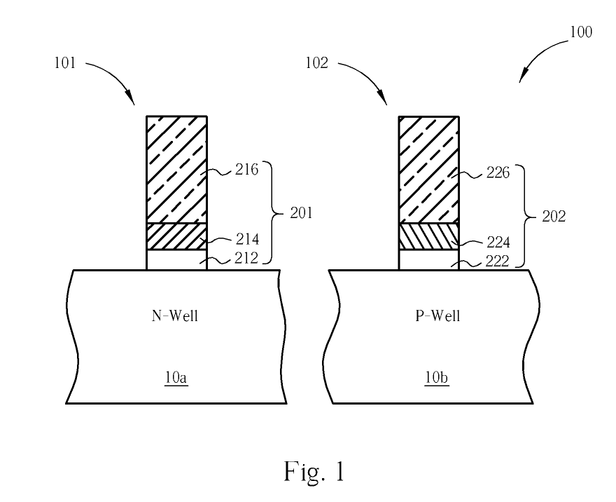

Please refer to FIG. 1. FIG. 1 is a cross-sectional view of a metal-gate CMOS device 100 according to the preferred embodiment of this invention. As shown in FIG. 1, the metal-gate CMOS device 100 comprises a PMOS transistor 101 and an NMOS transistor 102 coupled to the PMOS transistor 101. The PMOS transistor 101 and the NMOS transistor 102 are formed on a N-type substrate (N-well) 10a and a P-type substrate (P-well) 10b, respectively. The PMOS transistor 101 comprises a gate stack 201 and the NMOS transistor 102 comprises a gate stack 202.

The gate stack 201 of the PMOS transistor 101 consists of a dielectric layer 212, a single-layer metal 214 directly stacked on the dielectric layer 212, and a conductive capping layer 216 directly stacked on the single-layer metal 214. The gate stack 202 of the NMOS transistor 102 consists of dielectric layer 222, a single-layer metal 224 directly stacked on the dielectric layer 222, and a conductive capping layer 226 directly stacked on the single-layer metal 214. The single-layer metal 214 has a first work function tuned for the PMOS, while the single-layer metal 224 has a second work function tuned for the NMOS. For the sake of simplicity, some devices such as shallow trench isolation or diffusion source/drain are not explicitly shown in this and following figures.

The single-layer metal 214 is a layer of single metal material having a work function of about 4 eV. For example, the single-layer metal 214 may be composed of amorphous TaNₓ or TiN. The thickness of the single-layer metal 214 is less than 500 angstroms, preferably less than 400 angstroms. The single-layer metal 224 is a layer of single metal material having a higher work function of about 5 eV. For example, the single-layer metal 224 may be composed of TaRu alloys such as TaRuₓN_{y}(x=1.2˜1.3, y=0.4˜0.6). The thickness of the single-layer metal 224 is less than 500 angstroms, preferably less than 400 angstroms.

According to the preferred embodiment of this invention, the dielectric layer 12 is composed of materials having a relatively higher dielectric constant than that of silicon dioxide. For example, the dielectric layer 12 may be composed of ZrO₂, HfO₂, Zr silicates, Hf silicates, or Al doped Zr silicates. Preferably, the dielectric layer 12 is composed of ZrO₂, HfO₂, (ZrO₂)ₓ(SiO₂)_{y}, (HfO₂)ₓ(SiO₂)_{y} or (ZrO₂)(Al₂O₃)ₓ(SiO₂)_{y}.

The conductive capping layer 216 that is directly stacked on the single-layer metal 214 may comprise polysilicon, doped polysilicon, tungsten and silicide. The conductive capping layer 226 that is directly stacked on the single-layer metal 224 may comprise polysilicon, doped polysilicon and silicide. The thickness of the conductive capping layers 216 and 226 ranges from 2000 angstroms to 6000 angstroms.

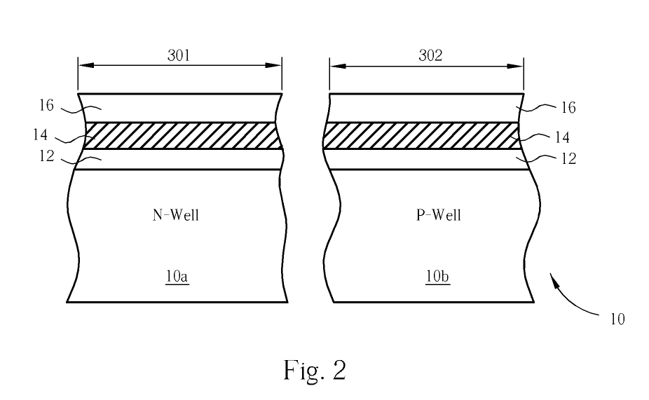

Please refer to FIG. 2 to FIG. 7. FIG. 2 to FIG. 7 are schematic diagrams showing an exemplary method of forming a metal-gate CMOS device according to this invention. First, as shown in FIG. 2, a semiconductor substrate 10 is provided. On the substrate 10 there are provided an N-well 10a and a P-well 10b within a PMOS region 301 and a NMOS region 302 respectively. Generally, shallow trench isolation (STI) regions or field oxide regions and active regions are previously defined on the substrate 10, but are not shown in the figures for the sake of simplicity.

Typically, the surface of the substrate 10 is washed by using HF solution with a concentration of 100:1 (H₂O:HF) in volume. Thereafter, a conventional nitridation process is carried out by using RTP methods. Details of these surface pre-treatment steps are known in the art and are therefore omitted. After the above-mentioned surface pre-treatment steps, a high-K dielectric layer 12 is deposited onto the surface of the semiconductor substrate 10 in the PMOS region 301 and NMOS region 302. According to the preferred embodiment of this invention, the high-K dielectric layer 12 is composed of materials having a high dielectric constant. For example, the dielectric layer 12 may be composed of ZrO₂, HfO₂, Zr silicates, Hf silicates, or Al doped Zr silicates. Preferably, the dielectric layer 12 is composed of ZrO₂, HfO₂, (ZrO₂)ₓ(SiO₂)_{y}, (HfO₂)ₓ(SiO₂)_{y} or (ZrO₂)(Al₂O₃)ₓ(SiO₂)_{y}.

After the deposition of the high-K dielectric layer 12, a layer of metal material 14 having a first work function tuned for the PMOS is formed on the high-K dielectric layer 12. For example, the metal material layer 14 may comprise amorphous TaNₓ or TiN. Preferably, the metal material layer 14 has a thickness of about 100-300 angstroms. Subsequently, a silicon nitride cap layer 16 is formed on the metal material layer 14.

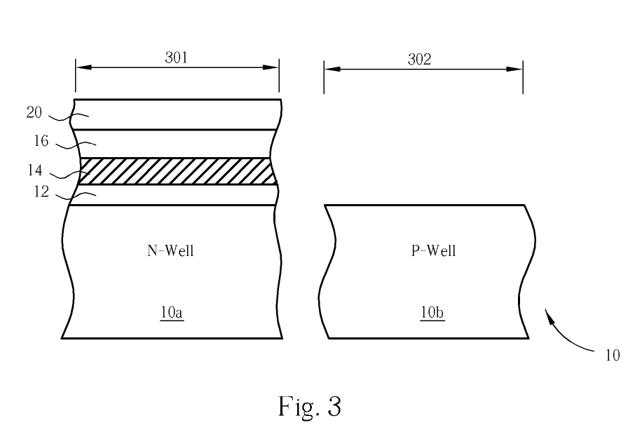

As shown in FIG. 3, the PMOS region 301 is masked by a photoresist layer 20, while the NMOS region 302 is exposed. The silicon nitride cap layer 16, the metal material layer 14 and the high-K dielectric layer 12 within the exposed NMOS region 302 are etched away. The photoresist layer 20 is then stripped.

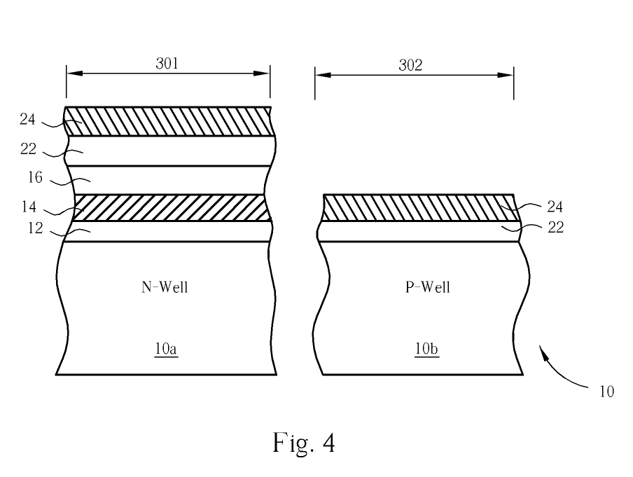

As shown in FIG. 4, another high-K dielectric layer 22 is deposited over the semiconductor substrate 10. The high-K dielectric layer 22, which covers the silicon nitride cap layer 16 within the PMOS region 301 and covers the semiconductor substrate within the NMOS region 302, may comprise ZrO₂, HfO₂, Zr silicates, Hf silicates, or Al doped Zr silicates. Preferably, the dielectric layer 12 is composed of ZrO₂, HfO₂, (ZrO₂)ₓ(SiO₂)_{y}, (HfO₂)ₓ(SiO₂)_{y} or (ZrO₂)(Al₂O₃)ₓ(SiO₂)_{y}. After the deposition of the high-K dielectric layer 22, another layer of metal material 24 having a second work function tuned for the NMOS is formed on the high-K dielectric layer 22. For example, the metal material layer 24 may comprise TaRu alloys such as TaRuₓN_{y}(x=1.2˜1.3, y=0.4˜0.6) or PVD deposited TaN. Preferably, the metal material layer 24 has a thickness of about 100-300 angstroms.

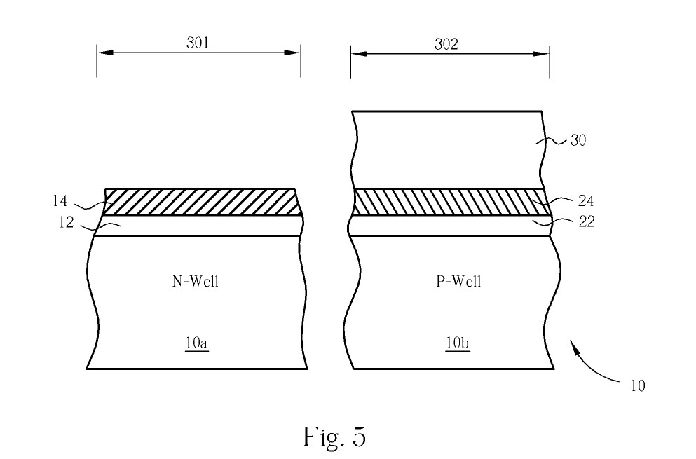

As shown in FIG. 5, the NMOS region 302 is masked by a photoresist layer 30, while the PMOS region 301 is now exposed. The metal material layer 24, the high-K dielectric layer 22 and the silicon nitride cap layer 16 within the exposed PMOS region 301 is then etched away using methods known in the art. For example, the silicon nitride cap layer 16 may be etched away using wet etchant such as heated phosphoric acid solution. The photoresist layer 30 is then stripped.

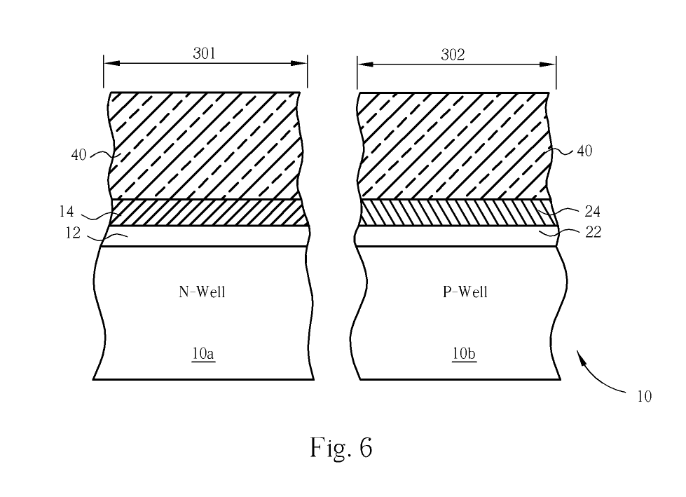

As shown in FIG. 6, a chemical vapor deposition (CVD) process is performed to deposit a doped polysilicon layer 40 over the semiconductor substrate 10. The doped polysilicon layer 40 covers regions 301 and 302. Preferably, the doped polysilicon layer 40 has a thickness of about 2000 angstroms to 6000 angstroms, but not limited thereto. Optionally, a silicide process or self-aligned silicide process may be carried out to convert an upper portion of the doped polysilicon layer 40 into a silicide layer. Alternatively, the salicide process may be performed at a later stage. For example, the salicide process may be carried out simultaneously with the source/drain salicide process.

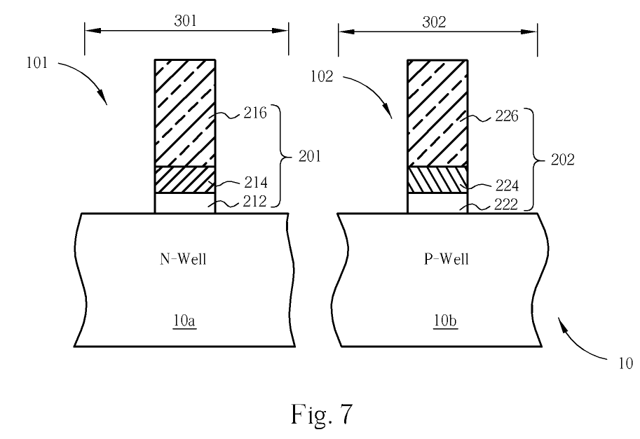

As shown in FIG. 7, a lithographic process and a dry etching process are performed to form gate stack 201 and gate stack 202. The gate stack 201 of the PMOS transistor 101 consists of a dielectric layer 212, a single-layer metal 214 directly stacked on the dielectric layer 212, and a conductive capping layer 216 directly stacked on the single-layer metal 214. The gate stack 202 of the NMOS transistor 102 consists of dielectric layer 222, a single-layer metal 224 directly stacked on the dielectric layer 222, and a conductive capping layer 226 directly stacked on the single-layer metal 214. To complete the PMOS transistor 101 and the NMOS transistor 102, gate sidewall spacers (not shown) are formed and source/drain regions (not shown) are implanted into the substrate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A metal-gate complementary metal-oxide-semiconductor (CMOS) device, comprising:
a PMOS transistor formed on a first area of a substrate, comprising a first gate stack consisting of a first dielectric layer, a first single-layer metal directly stacked on the first dielectric layer, and a first conductive capping layer directly stacked on the first single-layer metal; and
a NMOS transistor formed on a second area of the substrate and being coupled to the PMOS transistor, the NMOS transistor comprising a second gate stack consisting of a second dielectric layer, a second single-layer metal directly stacked on the second dielectric layer, and a second conductive capping layer directly stacked on the second single-layer metal.

2. The CMOS device according to claim 1 wherein the first single-layer metal is composed of amorphous TaNₓ or TiN.

3. The CMOS device according to claim 2 wherein the first single-layer metal has a thickness of about 100-300 angstroms.

4. The CMOS device according to claim 1 wherein the second single-layer metal is composed of TaRu alloys.

5. The CMOS device according to claim 4 wherein the second single-layer metal has a thickness of about 100-300 angstroms.

6. The CMOS device according to claim 1 wherein the first conductive capping layer comprises polysilicon.

7. The CMOS device according to claim 6 wherein the first conductive capping layer further comprises silicide.

8. The CMOS device according to claim 6 wherein the first conductive capping layer has a thickness of about 2000-6000 angstroms.

9. The CMOS device according to claim 1 wherein the second conductive capping layer comprises polysilicon.

10. The CMOS device according to claim 8 wherein the second conductive capping layer further comprises silicide.

11. The CMOS device according to claim 1 wherein the first dielectric layer comprises ZrO₂, HfO₂, Zr silicates, Hf silicates or Al doped Zr silicates.

12. The CMOS device according to claim 1 wherein the second dielectric layer comprises ZrO₂, HfO₂, Zr silicates, Hf silicates or Al doped Zr silicates.

13. A method of fabricating a metal-gate complementary metal-oxide-semiconductor (CMOS) device, comprising:
providing a semiconductor substrate having a first region and a second region;
depositing a first dielectric layer over the semiconductor substrate;
depositing a first metal layer over the first dielectric layer;
depositing a capping layer over the first metal layer;
masking the first region while exposing the second region;
etching away the capping layer, the first metal layer and the first dielectric layer from the second region;
depositing a second dielectric layer over the semiconductor substrate, the second dielectric layer covering the capping layer;
depositing a second metal layer over the second dielectric layer;
masking the second region while exposing the first region;
etching away the second metal layer, the second dielectric layer and the capping layer from the first region;
depositing a conductive layer on the first metal layer and on the second metal layer; and
performing lithographic and etching processes to form a first gate stack comprising the first dielectric layer, the first metal layer and the conductive layer within the first region, and a second gate stack comprising the second dielectric layer, the second metal layer and the conductive layer within the second region.

14. The method according to claim 13 wherein the first metal layer is composed of amorphous TaNₓ or TiN.

15. The method according to claim 13 wherein the second metal layer is composed of TaRu alloys.

16. The method according to claim 13 wherein the first dielectric layer comprises ZrO₂, HfO₂, Zr silicates, Hf silicates or Al doped Zr silicates.

17. The method according to claim 13 wherein the second dielectric layer comprises ZrO₂, HfO₂, Zr silicates, Hf silicates or Al doped Zr silicates.

18. The method according to claim 13 wherein the capping layer comprises silicon nitride.

19. The method according to claim 13 wherein the conductive layer comprises polysilicon.

20. The method according to claim 13 wherein the first metal layer has a thickness of about 100-300 angstroms.

21. The method according to claim 13 wherein the second metal layer has a thickness of about 100-300 angstroms.
